(19) United States
(12) Patent Application Publication
(10) Pub. No.: US 2026/0333972 A1
(43) Pub. Date: Oct. 22, 2026

(54) DISPLAY DEVICE INCLUDING LIGHT EMITTING DIODE

(71) Applicant: LG Display Co., Ltd., Seoul (KR)

(72) Inventor: Ho-Jin RYU, Paju-si (KR)

(73) Assignee: LG Display Co., Ltd., Seoul (KR)

(21) Appl. No.: 19/639,117

(22) Filed: Apr. 3, 2026

(30) Foreign Application Priority Data
Apr. 21, 2025 (KR) 10-2025-0051550

(51) Int. Cl. H10H 29/39; H10H 29/49

(52) U.S. Cl. CPC H10H 29/39; H10H 29/49

(57) ABSTRACT

A display device having a plurality of subpixels includes in one of the subpixels: a transistor and a power line on a substrate; a first connecting electrode on and connected to the transistor; a second connecting electrode on and connected to the power line; an adhesive layer on the first and second connecting electrodes, the adhesive layer including a compensating hole exposing the second connecting electrode; a main light emitting diode chip on the adhesive layer; a third connecting electrode on the adhesive layer, the third connecting electrode being connected to the first connecting electrode and the main light emitting diode chip; and a fourth connecting electrode on the adhesive layer, the fourth connecting electrode being connected to the second connecting electrode through the compensating hole and connected to the main light emitting diode chip.

### CROSS-REFERENCE TO RELATED APPLICATION

The present application claims the priority of Republic of Korea Patent Application No. 10-2025-0051550, filed on Apr. 21, 2025, which is hereby incorporated by reference in its entirety.

### BACKGROUND

### Field of the Disclosure

The present disclosure relates to a display device, and more particularly, to a display device including a light emitting diode where a main chip of an abnormal operation is replaced with a repair chip.

### Description of the Background

Recently, various flat panel display devices, such as a liquid crystal display device (LCD), an organic light emitting diode (OLED) display device, and a field emission display (FED) device, having excellent properties of a thin profile, a light weight, and a low power consumption have been developed and applied to various fields.

Although the OLED display device among the various flat panel display devices has an advantage in that an additional light source is not required, the OLED display device has a disadvantage in that deterioration may occur due to an external circumstance because of a property of an organic material being vulnerable to moisture and oxygen.

To overcome the disadvantage, a display device using a light emitting diode (LED) chip (or a light emitting diode (LED)) of an inorganic material has been suggested.

The light emitting diode chip is attached to a display panel after the light emitting diode chip is formed on a growth substrate. When a main chip of a light emitting diode attached to a subpixel of a display panel operates abnormally, the display panel is repaired by attaching a repair chip of a light emitting diode to the subpixel of the display panel.

Where a vertical-type light emitting diode chip is attached to the display panel through a side contact method, the display panel may not be repaired due to such failure as an electric short where a semiconductor layer of the externally exposed repair chip is connected to a second electrode through a connecting electrode.

### SUMMARY

Accordingly, the present disclosure is directed to a display device that substantially obviates one or more of the problems due to limitations and disadvantages of the related art.

More specifically, an object of the present disclosure is to provide a display device where an electric short between a semiconductor layer and a second electrode of a repair chip is prevented or suppressed, and a fabrication process is optimized or improved by forming a compensating hole corresponding to the repair chip in an adhesive layer.

In addition, an object of the present disclosure is to provide a display device where a repair rate is improved and a fabrication cost is reduced by forming a compensating hole in an adhesive layer and disposing a repair chip on a fourth connecting electrode in the compensating hole.

Additional features and advantages of the present disclosure will be set forth in the description which follows, and in part will be apparent from the description, or may be learned by practice of the disclosure. These and other advantages of the disclosure can be realized and attained by the structure particularly pointed out in the written description and claims hereof as well as the appended drawings.

To achieve these and other advantages and in accordance with the purpose of the present disclosure, as embodied and broadly described herein, a display device includes: a substrate including a subpixel having a light emitting diode; a transistor and a power line on the substrate; a first planarizing layer on the transistor and the power line; a first connecting electrode and a second connecting electrode on the first planarizing layer, the first and second connecting electrodes being connected to the transistor and the power line, respectively; an adhesive layer on the first and second connecting electrodes, the adhesive layer having a compensating hole exposing the second connecting electrode; a main chip of the light emitting diode on the adhesive layer; a third connecting electrode on the adhesive layer, the third connecting electrode being connected to the first connecting electrode; a fourth connecting electrode on the adhesive layer, the fourth connecting electrode being connected to the second connecting electrode through the compensating hole and connected to the main chip; and a second planarizing layer on the third and fourth connecting electrodes.

In another aspect, a display device having a plurality of subpixels includes in one of the subpixels: a transistor and a power line on a substrate; a first connecting electrode on and connected to the transistor; a second connecting electrode on and connected to the power line; an adhesive layer on the first and second connecting electrodes, the adhesive layer including a compensating hole exposing the second connecting electrode; a main light emitting diode chip on the adhesive layer; a third connecting electrode on the adhesive layer, the third connecting electrode being connected to the first connecting electrode and the main light emitting diode chip; and a fourth connecting electrode on the adhesive layer, the fourth connecting electrode being connected to the second connecting electrode through the compensating hole and connected to the main light emitting diode chip.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this specification, illustrate example embodiments of the present disclosure and together with the description serve to explain various principles of the present disclosure. In the drawings:

FIG. 1 is a view showing a display device according to an example embodiment of the present disclosure;

FIG. 2 is a view showing a subpixel of a display device according to an example embodiment of the present disclosure;

FIG. 3 is a plan view showing an unrepaired subpixel of a display panel of a display device according to an example embodiment of the present disclosure;

FIG. 4 is an example cross-sectional view taken along line IV-IV in FIG. 3;

FIG. 5 is a plan view showing a repaired subpixel of a display panel of a display device according to an example embodiment of the present disclosure;

FIG. 6 is an example cross-sectional view taken along line VI-VI in FIG. 5; and

FIGS. 7A -7E are cross-sectional views (e.g., along line VI-VI as shown in FIG. 5) showing a method of repairing a display device according to an example embodiment of the present disclosure.

### DETAILED DESCRIPTION

Advantages and features of the present disclosure, and implementation methods thereof will be clarified through following example aspects or embodiments described with reference to the accompanying drawings. The present disclosure may, however, be embodied in different forms and should not be construed as limited to the example aspects or embodiments set forth herein. Rather, these example aspects or embodiments are provided so that this disclosure may be sufficiently thorough and complete to assist those skilled in the art to more fully understand the scope of the present disclosure.

The shapes, sizes, dimensions (e.g., length, width, height, thickness, radius, diameter, area, etc.), ratios, angles, number of elements, and the like illustrated in the accompanying drawings for describing the example embodiments of the present disclosure are merely examples, and the present disclosure is not limited thereto.

A dimension including a size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless a more specific term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly),” is used. For example, where an element or layer is described as disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to refer to one element separately from another. For example, a first element could be termed a second element, and, similarly, a second element could be termed a first element, without departing from the scope of the present disclosure.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” should be interpreted in the same manner.

The term “at least one” should be understood to include all combinations of one or more of related elements. For example, the term of “at least one of first, second, and third elements” may include all combinations of two or more of the first, second, and third elements as well as the first, second, or third element individually.

The term “display device” may include a display device in a narrow sense, such as liquid crystal module (LCM), an organic light emitting diode (OLED) module, and a quantum dot (QD) module, including a display panel and a driving unit for driving the display panel. In addition, the term “display device” may include a complete product (or a final product) including the LCM, the OLED module, or the QD module, such as a notebook or laptop computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of according to example embodiments of the present disclosure may include an applied product or a set device of a final user’s device including the LCM, the OLED module, or the QD module, as well as a display device in a narrow sense such as the LCM, the OLED module, or the QD module.

According to circumstances, the LCM, the OLED module, or the QD module having a display panel and a driving unit may be expressed as “a display device,” and an electronic apparatus of a complete product including the LCM, the OLED module, or the QD module may be expressed as “a set device.” For example, a display device in a narrow sense may include a display panel of a liquid crystal, an organic light emitting diode, or a quantum dot, and a source printed circuit board (PCB) of a control unit for driving the display panel, and a set device may further include a set PCB of a set control unit electrically connected to the source PCB for controlling the entire set device.

The display panel according to example embodiments of the present disclosure may include all kinds of display panels such as a liquid crystal display panel, an organic light emitting diode display panel, a quantum dot display panel, and an electroluminescent display panel. The display panel according to example embodiments of the present disclosure may include, but is not limited to, a specific display panel of a bezel bending having a flexible substrate for an organic light emitting diode display panel and a lower back plate supporter. A shape or a size of the display panel for the display device according to example embodiments of the present disclosure is not limited thereto.

For example, where the display panel is an organic light emitting diode display panel, the display panel may include a plurality of gate lines, a plurality of data lines, and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, the emitting element layer on the array may include, for example, an inorganic light emitting layer, a nano-sized material layer, or a quantum dot.

The thin film transistor of according to example embodiments the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. These various embodiments or aspects may be carried out independently of or in association with each other in various combinations.

Hereinafter, with reference to the accompanying drawings, a display device according to various example embodiments of the present disclosure will be described in detail where an area of a non-display area is reduced and a narrow bezel is obtained by forming a plurality of power supply lines having the same material from the same layer and as a bridge pattern for sensing a touch to overlap an auxiliary circuit unit.

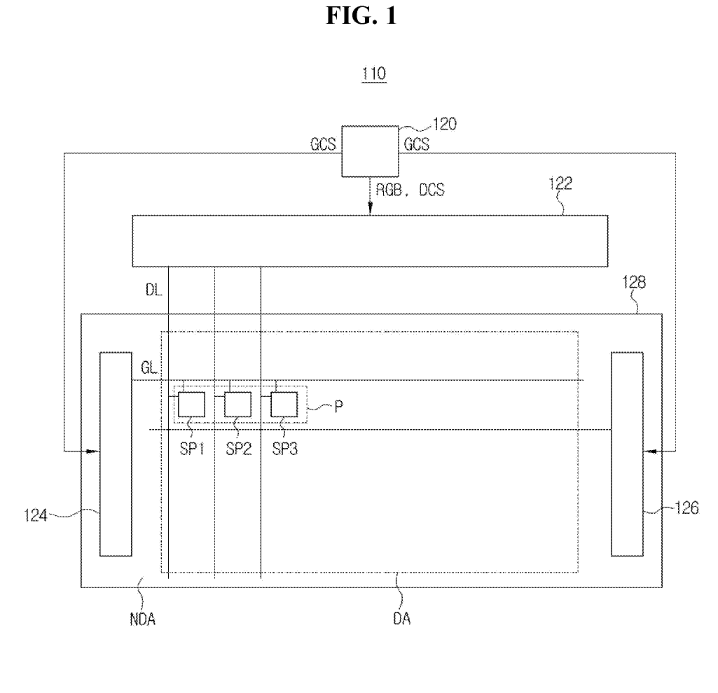

FIG. 1 is a view showing a display device according to an example embodiment of the present disclosure. Although the display device may be, for example, an organic light emitting diode (OLED) display device, it is not limited thereto. For example, the display device may be a quantum dot display device, a micro light emitting diode (LED) display device, or a mini light emitting diode (LED) display device.

In FIG. 1, a display device 110 according to an example embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS, and a gate control signal GCS using an image signal and a plurality of timing signals including a data enable signal, a horizontal synchronization signal, a vertical synchronization signal and a clock signal received from an external system such as a graphic card or a television system.

The timing controlling unit 120 transmits the image data RGB and the data control signal DCS to the data driving unit 122, and transmits the gate control signal GCS to the first and second gate driving units 124 and 126.

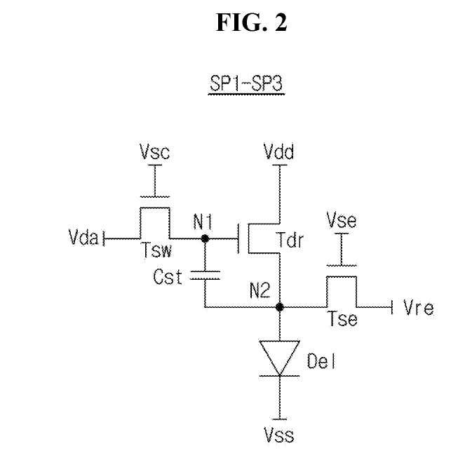

The data driving unit 122 generates a data signal (a data voltage) Vda (see, e.g., FIG. 2) using the image data RGB and the data control signal DCS received from the timing controlling unit 120 and transmits the data signal Vda to a data line DL of the display panel 128.

The first and second gate driving units 124 and 126 generate gate signals (gate voltages) Vsc and Vse (of FIG. 2) using the gate control signal GCS received from the timing controlling unit 120 and applies the gate signals Vsc and Vse to respective gate lines GL of the display panel 128.

The first and second gate driving units 124 and 126 may of a gate in panel (GIP) type to be formed in a non-display area NDA of a substrate of the display panel 128 having the gate lines GL, the data lines DL, and pixels P.

Although the first and second gate driving units 124 and 126 are disposed in opposing side portions of the display panel 128 in the example embodiment of FIG. 1, one gate driving unit may be disposed in one side portion of the display panel 128 in another example embodiment.

The display panel 128 includes a display area DA at a central portion thereof and a non-display area NDA surrounding the display area DA. The display panel 128 displays an image using the gate signals Vsc and Vse and the data signal Vda. Hereinafter, the gate signals Vsc and Vse may be referred to as a scan signal Vsc and a sensing signal Vse, respectively.

For displaying an image, the display panel 128 includes a plurality of pixels P, a plurality of gate lines GL, and a plurality of data lines DL in the display area DA.

In an example embodiment, each of the plurality of pixels P includes first, second, and third subpixels SP1, SP2, and SP3, and a corresponding gate line GL and corresponding data lines DL cross each other to define the first, second, and third subpixels SP1, SP2, and SP3, respectively. Each of the first, second, and third subpixels SP1, SP2, and SP3 is connected to the corresponding gate line GL and the corresponding data line DL. For example, the first, second, and third subpixels SP1, SP2, and SP3 may correspond to red, green, and blue colors, respectively.

In another example embodiment, each of the plurality of pixels P includes first, second, third, and fourth subpixels SP1, SP2, SP3, and SP4 corresponding to red, green, blue, and white colors, respectively.

Each of the first, second, and third subpixels SP1, SP2 and SP3 may include a plurality of transistors, such as a switching transistor Tsw (see, e.g., FIG. 2), a driving transistor Tdr (see, e.g., FIG. 2), and a sensing transistor Tse (see, e.g., FIG. 2), a storage capacitor Cst (see, e.g., FIG. 2), and a light emitting diode Del (see, e.g., FIG. 2).

FIG. 2 is a view showing a subpixel of a display device according to an example embodiment of the present disclosure.

In FIG. 2, each of the first, second, and third subpixels SP1, SP2, and SP3 of the display device 110 according to an example embodiment of the present disclosure includes a switching transistor Tsw, a driving transistor Tdr, a sensing transistor Tse, a storage capacitor Cst, and a light emitting diode Del.

Although each of the first, second, and third subpixels SP1, SP2, and SP3 has a 3T1C structure having three transistors and one storage capacitor in the example embodiment of FIG. 2, each of the first, second, and third subpixels SP1, SP2 and SP3 may have one of a 6T1C structure having six transistors and one storage capacitor, a 7T1C structure having seven transistors and one storage capacitor, a 8T1C structure having eight transistors and one storage capacitor, etc., in one or more other example embodiments.

Although the switching transistor Tsw, the driving transistor Tdr, and the sensing transistor Tse may have a negative type (N type) in the example embodiment of FIG. 2, at least one of the switching transistor Tsw, the driving transistor Tdr, and the sensing transistor Tse may have a positive type (P type) in another example embodiment.

The switching transistor Tsw is switched on or off according to a scan signal Vsc to transmit a data signal Vda to a first node N1.

A gate electrode of the switching transistor Tsw is connected to a gate line GL to receive the scan signal Vsc via the gate line GL, a drain electrode of the switching transistor Tsw is connected to a data line DL to receive the data signal Vda via the data line DL, and a source electrode of the switching transistor Tsw is connected to the first node N1.

The driving transistor Tdr is switched on or off according to a voltage of the first node N1 to transmit a high level supply voltage signal (high level supply voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched on or off according to a sensing signal (sensing voltage) Vse to transmit a reference signal (reference voltage) Vre to the second node N2 or to transmit a voltage of the second node N2 to a reference line.

A gate electrode of the sensing transistor Tse is connected to a gate line GL to receive the sensing signal Vse from the gate line GL, a drain electrode of the sensing transistor Tse is connected to the reference line to receive the reference signal Vre from the reference line or to transmit a voltage of the second node N2 to the reference line, and a source electrode of the sensing transistor Tse is connected to the second node N2. For example, the gate line GL connected to the gate electrode of the sensing transistor Tse may be the same gate line GL connected to the gate electrode of of the switching transistor Tsw or may be another gate line GL from the one connected to the gate electrode of of the switching transistor Tsw.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits light of a luminance proportional to a current of or through the driving transistor Tdr.

An anode of the light emitting diode Del is connected to the second node N2, and a cathode of the light emitting diode Del is connected to a low level power line to receive a low level supply voltage signal (low level supply voltage) Vss.

The source electrode of the switching transistor Tsw, the gate electrode of the driving transistor Tdr, and the first capacitor electrode of the storage capacitor Cst constitute (or are connected to) the first node N1, and the source electrode of the driving transistor Tdr, the source electrode of the sensing transistor Tse, the second capacitor electrode of the storage capacitor Cst, and the anode of the light emitting diode Del constitute (or are connected to) the second node N2.

The light emitting diode Del may emit a light having a luminance corresponding to the corresponding image data RGB according to a driving of a corresponding one of the subpixel circuits of the first, second, and third subpixels SP1, SP2, and SP3.

In the example display device 110 in FIG. 1, each of the first, second, and third subpixels SP1, SP2, and SP3 includes a region for attaching a main chip of the light emitting diode Del and a region for attaching a repair chip of the light emitting diode Del. After the main chip is attached, a lighting test is performed. The display panel 128 may be repaired by additionally attaching a repair chip to the subpixel where the main chip is determined to operate abnormally (e.g., fail to emit light).

A planar structure and a cross-sectional structure of each of the first, second, and third subpixels SP1, SP2, and SP3 of the display panel 128 of the display device 110 will be illustrated with reference to drawings.

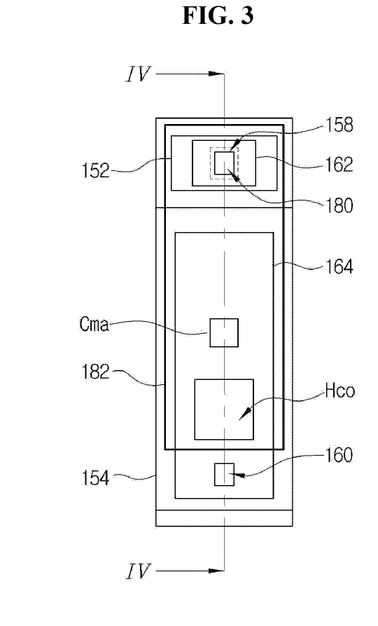

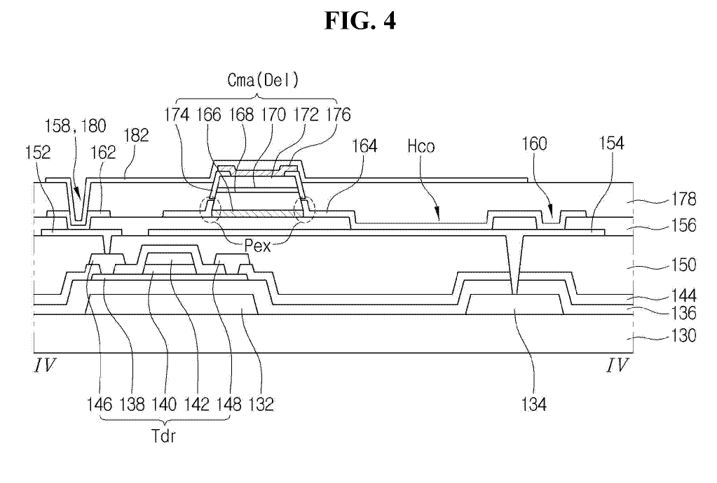

FIG. 3 is a plan view showing an unrepaired subpixel of a display panel of a display device according to an example embodiment of the present disclosure, and FIG. 4 is an example cross-sectional view taken along line IV-IV in FIG. 3.

In FIGS. 3 and 4, a light shielding pattern 132 and the low level power line 134 are disposed in each of the first, second, and third subpixels SP1, SP2, and SP3 on a substrate 130, and a buffer layer 136 is disposed on the light shielding pattern 132 and the low level power line 134 over the entire substrate 130.

The light shielding pattern 132 may block light incident from a lower portion of the substrate 130, and the low level power line 134 may supply the low level supply voltage Vss.

The light shielding pattern 132 and the low level power line 134 may include the same material from the same layer as each other.

For example, the light shielding pattern 132 and the low level power line 134 may have a single layer or multiple layers of metallic material(s), such as molybdenum (Mo), aluminum (Al), chromium (Cr), gold (Au), titanium (Ti), nickel (Ni), neodymium (Nd), copper (Cu), and/or an alloy thereof.

The buffer layer 136 may block moisture or oxygen permeating from an exterior.

For example, the buffer layer 136 may have a single layer or multiple layers of inorganic insulating material(s), such as silicon oxide (SiO2) and/or silicon nitride (SiNx).

A semiconductor layer 138 is disposed on the buffer layer 136 to overlap the light shielding pattern 132, and a gate insulating layer 140 is disposed on a central portion of the semiconductor layer 138.

The semiconductor layer 138 includes a channel region not doped with an impurity at a central portion thereof and source and drain regions doped with an impurity at both side portions of the channel region.

For example, the semiconductor layer 138 may include a polycrystalline semiconductor material, such as polycrystalline silicon, or an oxide semiconductor material, such as indium gallium zinc oxide (IGZO), zinc oxide (ZnO), tin oxide (SnO2), copper oxide (Cu2O), nickel oxide (NiO), indium tin zinc oxide (ITZO), or indium aluminum zinc oxide (IAZO).

For example, the gate insulating layer 140 may have a single layer or multiple layers of inorganic insulating material(s), such as silicon oxide (SiO2) and/or silicon nitride (SiNx).

A gate electrode 142 is disposed on the gate insulating layer 140 to overlap the channel region of the semiconductor layer 138, and an interlayer insulating layer 144 is disposed on the gate electrode 142 over the entire substrate 130.

For example, the gate electrode 142 may have a single layer or multiple layers of metallic material(s), such as molybdenum (Mo), aluminum (Al), chromium (Cr), gold (Au), titanium (Ti), nickel (Ni), neodymium (Nd), copper (Cu), and/or an alloy thereof.

For example, the interlayer insulating layer 144 may have a single layer or multiple layers of inorganic insulating material(s), such as silicon oxide (SiO2) and/or silicon nitride (SiNx).

A source electrode 146 and a drain electrode 148 spaced apart from each other are disposed on the interlayer insulating layer 144, and a first planarizing layer 150 is disposed on the source electrode 146 and the drain electrode 148 over the entire substrate 130.

The source electrode 146 and the drain electrode 148 are connected to the source region and the drain region, respectively, of the semiconductor layer 138 through contact holes in the interlayer insulating layer 144.

Although not shown, the drain electrode 148 may be connected to the light shielding pattern 132 through a contact hole in the interlayer insulating layer 144 and the buffer layer 136.

The source electrode 146 and the drain electrode 148 may include the same material from the same layer as each other.

For example, the source electrode 146 and the drain electrode 148 may have a single layer or multiple layers of metallic material(s), such as molybdenum (Mo), aluminum (Al), chromium (Cr), gold (Au), titanium (Ti), nickel (Ni), neodymium (Nd), copper (Cu), and/or an alloy thereof.

For example, the first planarizing layer 150 may have a single layer or multiple layers of organic insulating material(s), such as photoacryl and/or benzocyclobutene (BCB).

The semiconductor layer 138, the gate electrode 142, the source electrode 146, and the drain electrode 148 may constitute the driving transistor Tdr.

Although not shown, the first capacitor electrode and the second capacitor electrode may be disposed in each of the first, second, and third subpixels SP1, SP2, and SP3. The first capacitor electrode may include the same material from the same layer as the gate electrode 142, and the second capacitor electrode may include the same material from the same layer as the source electrode 146 and the drain electrode 148. The first capacitor electrode, the interlayer insulating layer 144, and the second capacitor electrode may constitute the storage capacitor Cst (see, e.g., FIG. 2).

First and second connecting electrodes 152 and 154 spaced apart from each other are disposed on the first planarizing layer 150, and an adhesive layer 156 is disposed on the first and second connecting electrodes 152 and 154 over the entire substrate 130.

The first connecting electrode 152 is connected to the source electrode 146 through a contact hole in the first planarizing layer 150, and the second connecting electrode 154 is connected to the low level power line 134 through a contact hole in the first planarizing layer 150, the interlayer insulating layer 144, and the buffer layer 136.

The first and second connecting electrodes 152 and 154 may include the same material from the same layer as each other and may have an excellent reflectance property.

For example, the first and second connecting electrodes 152 and 154 may have a single layer or multiple layers of metallic material(s), such as molybdenum (Mo), aluminum (Al), chromium (Cr), gold (Au), titanium (Ti), nickel (Ni), neodymium (Nd), copper (Cu), and/or an alloy thereof.

The adhesive layer 156 has a first contact hole 158 exposing the first connecting electrode 152, a second contact hole 160 exposing the second connecting electrode 154, and a compensating hole Hco exposing the second connecting electrode 154.

For example, the adhesive layer 156 may include an organic insulating material such as an epoxy resin having an adhesive property and may have a thickness of about 1.5 µm to about 2.5 µm.

A third connecting electrode 162 is disposed on the adhesive layer 156 to overlap (or be disposed in) the first contact hole 158, and a fourth connecting electrode 164 spaced apart from the third connecting electrode 162 is disposed on the adhesive layer 156 to overlap (or be disposed in) the second contact hole 160 and the compensating hole Hco. The main chip Cma of the light emitting diode Del is disposed on the adhesive layer 156 between the first contact hole 158 and the compensating hole Hco.

The third connecting electrode 162 is connected to the first connecting electrode 152 through the first contact hole 158, and the fourth connecting electrode 164 is connected to the second connecting electrode 154 through the second contact hole 160 and the compensating hole Hco.

For example, the third and fourth connecting electrodes 162 and 164 may have a single layer or multiple layers of metallic material(s), such as molybdenum (Mo), aluminum (Al), chromium (Cr), gold (Au), titanium (Ti), nickel (Ni), neodymium (Nd), copper (Cu), and/or an alloy thereof.

The main chip Cma, in this example as a vertical-type light emitting diode Del, includes a first main electrode 166, a first main semiconductor layer 168, a main active layer 170, a second main semiconductor layer 172, a main passivation layer 174, and a second main electrode 176 sequentially on the adhesive layer 156.

The first main semiconductor layer 168 supplies an electron(s) of the first main electrode 166 to the main active layer 170, and the second main semiconductor layer 172 supplies a hole(s) of the second main electrode 176 to the main active layer 170. The main active layer 170 may generate light using the electron(s) and the hole(s).

For example, the first main electrode 166 may be a cathode, and may have a single layer or multiple layers of metallic material(s) having a relatively high reflectance, such as molybdenum (Mo), aluminum (Al), chromium (Cr), gold (Au), titanium (Ti), nickel (Ni), neodymium (Nd), copper (Cu), and/or an alloy thereof.

For example, the first main semiconductor layer 168 may include a negative type gallium nitride (n-GaN), and the second main semiconductor layer 172 may include a positive type gallium nitride (p-GaN). The main active layer 170 may include a multi quantum well (MQW). The main chip Cma may have a thickness of about 3 µm to about 4 µm.

The main passivation layer 174 covers an upper portion of a side surface of the first main semiconductor layer 168, a side surface of the main active layer 170, and a side surface and an edge portion of an upper surface of the second main semiconductor layer 172. The main passivation layer 174 may have a side exposing portion Pex exposing a side surface of the first main electrode 166 and a lower portion of the side surface of the first main semiconductor layer 168 and may have an upper open portion exposing a central portion of the upper surface of the second main semiconductor layer 172.

For example, the main passivation layer 174 may have a single layer or multiple layers of inorganic insulating material(s), such as silicon oxide (SiO2) and/or silicon nitride (SiNx).

The second main electrode 176 is disposed on an upper surface of the main passivation layer 174 and is connected to the upper surface of the second main semiconductor layer 172 through the upper open portion of the main passivation layer 174.

For example, the second main electrode 176 may be an anode and may include a transparent conductive material, such as indium tin oxide (ITO) and/or indium zinc oxide (IZO).

The fourth connecting electrode 164 is disposed at a periphery of the main chip Cma and is connected to a side surface of the first main electrode 166 and a lower portion of the side surface of the first main semiconductor layer 168 exposed through the side exposing portion Pex of the main passivation layer 174. In an example embodiment, on the side surface of the first main semiconductor layer 168, the main passivation layer 174 may be disconnected from the fourth connecting electrode 164, i.e., the main passivation layer 174 may be spaced apart from the fourth connecting electrode 164.

Since the fourth connecting electrode 164 is connected to the main chip Cma through a side contact type due to a self-alignment, an efficiency of space utilization is improved.

A second planarizing layer 178 is disposed on the third and fourth connecting electrodes 162 and 164 and at least a portion of the main chip Cma over the entire substrate 130, and a fifth connecting electrode 182 is disposed on the second planarizing layer 178 to overlap the third connecting electrode 162, the main chip Cma, and the compensating hole Hco.

The second planarizing layer 178 has a third contact hole 180 exposing the third connecting electrode 162. Also, a part of the main passivation layer 174 of the main chip Cma and the second main electrode 176 are exposed through the second planarizing layer 178.

For example, the second planarizing layer 178 may have a single layer or multiple layers of organic insulating material(s), such as photoacryl and/or benzocyclobutene (BCB), and may have a thickness of about 2 µm to about 5 µm.

The fifth connecting electrode 182 is connected to the third connecting electrode 162 through the third contact hole 180 and is connected to the second main electrode 176 of the main chip Cma exposed through the second planarizing layer 178.

For example, the fifth connecting electrode 182 may include a metallic material, such as molybdenum (Mo), aluminum (Al), chromium (Cr), gold (Au), titanium (Ti), nickel (Ni), neodymium (Nd), and/or copper (Cu), or a transparent conductive material, such as indium tin oxide (ITO) and/or indium zinc oxide (IZO).

Although not shown, an additional planarizing layer or an encapsulating layer may be further disposed on the fifth connecting electrode 182 over the entire substrate 130 for preventing or suppressing permeation of oxygen or moisture.

Where the main chip Cma of each of the first, second, and third subpixels SP1, SP2, and SP3 of the display device 110 according to an example embodiment of the present disclosure operates normally (for example, as determined during manufacturing or testing), a repair chip is not disposed in the compensating hole Hco of the adhesive layer 156 of the corresponding subpixel, and the second planarizing layer 178 fills the compensating hole Hco. The light emitting diode Del of the main chip Cma may receive the high level supply voltage Vdd through the first connecting electrode 152, the third connecting electrode 162, and the fifth connecting electrode 182 and may receive the low level supply voltage Vss through the low level power line 134, the second connecting electrode 154, and the fourth connecting electrode 164 to emit light.

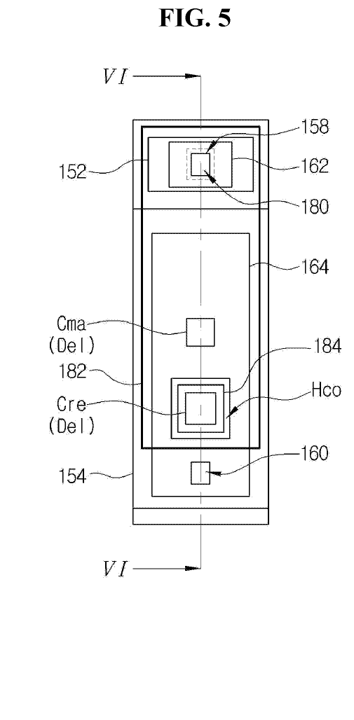

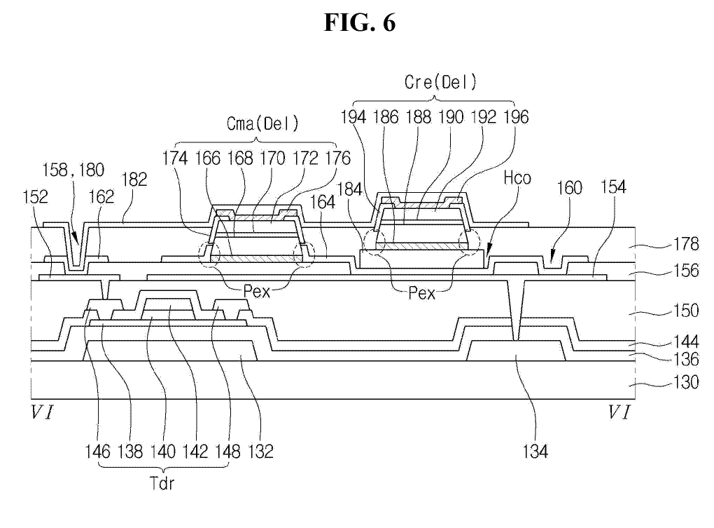

FIG. 5 is a plan view showing a repaired subpixel of a display panel of a display device according to an example embodiment of the present disclosure, and FIG. 6 is an example cross-sectional view taken along line VI-VI in FIG. 5. Illustration or detailed description of the same parts or elements described above with respect to FIGS. 3 and 4 may be omitted.

In FIGS. 5 and 6, the light shielding pattern 132 and the low level power line 134 are disposed in each of the first, second, and third subpixels SP1, SP2, and SP3 on the substrate 130, and the buffer layer 136 is disposed on the light shielding pattern 132 and the low level power line 134 over the entire substrate 130.

The semiconductor layer 138 is disposed on the buffer layer 136 to overlap the light shielding pattern 132, and the gate insulating layer 140 is disposed on a central portion of the semiconductor layer 138.

The gate electrode 142 is disposed on the gate insulating layer 140 to overlap the channel region of the semiconductor layer 138, and the interlayer insulating layer 144 is disposed on the gate electrode 142 over the entire substrate 130.

The source electrode 146 and the drain electrode 148 spaced apart from each other are disposed on the interlayer insulating layer 144, and the first planarizing layer 150 is disposed on the source electrode 146 and the drain electrode 148 over the entire substrate 130.

The semiconductor layer 138, the gate electrode 142, the source electrode 146, and the drain electrode 148 may constitute the driving transistor Tdr.

The first and second connecting electrodes 152 and 154 spaced apart from each other are disposed on the first planarizing layer 150, and the adhesive layer 156 is disposed on the first and second connecting electrodes 152 and 154 over the entire substrate 130.

The adhesive layer 156 has the first contact hole 158 exposing the first connecting electrode 152, the second contact hole 160 exposing the second connecting electrode 154, and the compensating hole Hco exposing the second connecting electrode 154.

The third connecting electrode 162 is disposed on the adhesive layer 156 to overlap (or be disposed in) the first contact hole 158, and the fourth connecting electrode 164 spaced apart from the third connecting electrode 162 is disposed on the adhesive layer 156 to overlap (or be disposed in) the second contact hole 160 and the compensating hole Hco. The main chip Cma of the light emitting diode Del is disposed on the adhesive layer 156 between the first contact hole 158 and the compensating hole Hco.

The third connecting electrode 162 is connected to the first connecting electrode 152 through the first contact hole 158, and the fourth connecting electrode 164 is connected to the second connecting electrode 154 through the second contact hole 160 and the compensating hole Hco.

The main chip Cma, in this example as a vertical-type light emitting diode Del, includes the first main electrode 166, the first main semiconductor layer 168, the main active layer 170, the second main semiconductor layer 172, the main passivation layer 174, and the second main electrode 176 sequentially on the adhesive layer 156.

The main passivation layer 174 covers the upper portion of the side surface of the first main semiconductor layer 168, the side surface of the main active layer 170, and a side surface and the edge portion of the upper surface of the second main semiconductor layer 172. The main passivation layer 174 may have the side exposing portion Pex exposing the side surface of the first main electrode 166 and the lower portion of the side surface of the first main semiconductor layer 168 and may have the upper open portion exposing the central portion of the upper surface of the second main semiconductor layer 172.

The second main electrode 176 is disposed on the upper surface of the main passivation layer 174 and is connected to the upper surface of the second main semiconductor layer 172 through the upper open portion of the main passivation layer 174.

The fourth connecting electrode 164 is disposed at a periphery of the main chip Cma and is connected to the side surface of the first main electrode 166 and the lower portion of the side surface of the first main semiconductor layer 168 through the side exposing portion Pex of the main passivation layer 174. In an example embodiment, on the side surface of the first main semiconductor layer 168, the main passivation layer 174 may be disconnected from the fourth connecting electrode 164, i.e., the main passivation layer 174 may be spaced apart from the fourth connecting electrode 164.

Where the main chip Cma operates abnormally, e.g., fails to emit light (for example, during manufacturing or testing), a conductive bonding layer 184 and a repair chip Cre of the light emitting diode Del are sequentially disposed on the fourth connecting electrode 164 in the compensating hole Hco of the adhesive layer 156.

The conductive bonding layer 184 electrically connects the fourth connecting electrode 164 and the repair chip Cre and fixes the repair chip Cre to the fourth connecting electrode 164.

For example, the conductive bonding layer 184 may include a material having a conductive property and an adhesive property and may be formed though a coating method such as an inkjet method. The conductive bonding layer 184 may have a thickness smaller than about 3.5 µm.

The repair chip Cre, in this example as a vertical-type light emitting diode Del, includes a first repair electrode 186, a first repair semiconductor layer 188, a repair active layer 190, a second repair semiconductor layer 192, a repair passivation layer 194, and a second repair electrode 196 sequentially on the conductive bonding layer 184.

The first repair electrode 186 directly contacts and is electrically connected to the conductive bonding layer 184.

For example, the first repair electrode 186 may be a cathode and may have a single layer or multiple layers of metallic material(s) having a relatively high reflectance, such as molybdenum (Mo), aluminum (Al), chromium (Cr), gold (Au), titanium (Ti), nickel (Ni), neodymium (Nd), copper (Cu), and/or an alloy thereof.

The first repair semiconductor layer 188 supplies an electron(s) of the first repair electrode 186 to the repair active layer 190, and the second repair semiconductor layer 192 supplies a hole(s) of the second repair electrode 196 to the repair active layer 190. The repair active layer 190 may generate light using the electron(s) and the hole(s).

For example, the first repair semiconductor layer 188 may include a negative type gallium nitride (n-GaN), and the second repair semiconductor layer 192 may include a positive type gallium nitride (p-GaN). The repair active layer 190 may include a multi quantum well (MQW). The repair chip Cre may have a thickness of about 3 µm to about 4 µm.

The repair passivation layer 194 covers an upper portion of a side surface of the first repair semiconductor layer 188, a side surface of the repair active layer 190, and a side surface and an edge portion of an upper surface of the second repair semiconductor layer 192. The repair passivation layer 194 may have a side exposing portion Pex exposing a side surface of the first repair electrode 186 and a lower portion of the side surface of the first repair semiconductor layer 188 and may have an upper open portion exposing a central portion of the upper surface of the second repair semiconductor layer 192.

For example, the repair passivation layer 194 may have a single layer or multiple layers of inorganic insulating material(s), such as silicon oxide (SiO2) and/or silicon nitride (SiNx).

The second repair electrode 196 is disposed on an upper surface of the repair passivation layer 194 and is connected to the upper surface of the second repair semiconductor layer 192 through the upper open portion of the repair passivation layer 194.

For example, the second repair electrode 196 may be an anode and may include a transparent conductive material, such as indium tin oxide (ITO) and/or indium zinc oxide (IZO).

The fourth connecting electrode 164 is connected to the first repair electrode 186 through the conductive bonding layer 184. A side surface of the first repair electrode 186 and a lower portion of the side surface of the first repair semiconductor layer 188 exposed through the side exposing portion Pex of the repair passivation layer 194 are covered with the second planarizing layer 178 in a subsequent step. As a result, the side surface of the first repair electrode 186 and the lower portion of the side surface of the first repair semiconductor layer 188 are not exposed through the second planarizing layer 178 so that an electric shortage (e.g., through the side exposing portion Pex of the repair passivation layer 194) can be prevented.

The upper surface of the second planarizing layer 178 is higher than the side exposing portion Pex of the repair passivation layer 194 and is lower than the upper surface of the second main semiconductor layer 172. In an example embodiment, the upper surface of the second planarizing layer 178 may be lower than an upper surface of the repair active layer 190.

In a display device according to a comparison example where the compensating hole Hco is not formed in the adhesive layer 156 of a region for attaching the repair chip Cre, the fourth connecting electrode 164, the conductive bonding layer 184, and the repair chip Cre are sequentially disposed on the adhesive layer 156. The lower portion of the side surface of the first repair semiconductor layer 188 exposed through the side exposing portion Pex of the repair passivation layer 194 is not covered with the second planarizing layer 178 and is exposed through the second planarizing layer 178. As a result, the lower portion of the side surface of the first repair semiconductor layer 188 exposed through the second planarizing layer 178 may be connected to the second repair electrode 196 due to the fifth connecting electrode 182 to cause such failure as an electric short.

In the display device 110 according to an example embodiment of the present disclosure where the compensating hole Hco is formed in the adhesive layer 156 at a region for attaching the repair chip Cre, the fourth connecting electrode 164, the conductive bonding layer 184, and the repair chip Cre are sequentially disposed on the second connecting electrode 154 exposed through the compensating hole Hco of the adhesive layer 156, and a step difference generated by the repair chip Cre is at least partially compensated for. Therefore, the lower portion of the side surface of the first repair semiconductor layer 188 exposed through the side exposing portion Pex of the repair passivation layer 194 is covered with the second planarizing layer 178 and is not exposed through the second planarizing layer 178. As a result, connection between the fifth connecting electrode 182 and the lower portion of the side surface of the first repair semiconductor layer 188 is blocked, and such failure as an electric short between the second repair electrode 196 and the lower portion of the side surface of the first repair semiconductor layer 188 can be prevented or suppressed so that a repair rate can be improved.

The second planarizing layer 178 is disposed on the third and fourth connecting electrodes 162 and 164, at least a portion of the main chip Cma, and at least a portion of the repair chip Cre over the entire substrate 130, and the fifth connecting electrode 182 is disposed on the second planarizing layer 178 to overlap the third connecting electrode 162, the main chip Cma, and the repair chip Cre.

The second planarizing layer 178 has the third contact hole 180 exposing the third connecting electrode 162. Also, a part of the main passivation layer 174, the second main electrode 176 of the main chip Cma, a part of the repair passivation layer 194, and the second repair electrode 196 of the repair chip Cre are exposed through the second planarizing layer 178.

The fifth connecting electrode 182 is connected to the third connecting electrode 162 through the third contact hole 180 and is connected to the second main electrode 176 of the main chip Cma and the second repair electrode 196 of the repair chip Cre exposed through the second planarizing layer 178.

Although not shown, an additional planarizing layer or an encapsulating layer may be further disposed on the fifth connecting electrode 182 over the entire substrate 130 for preventing or suppressing permeation of oxygen or moisture.

A method of repairing the display device according to an example embodiment of the present disclosure will be illustrated with reference to drawings.

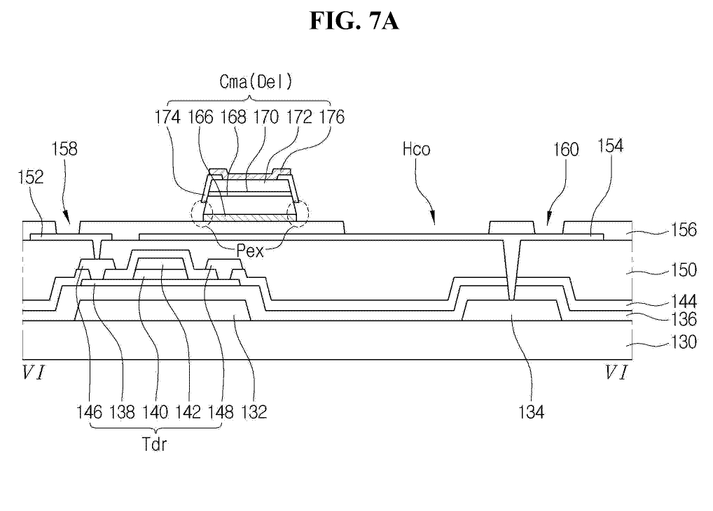

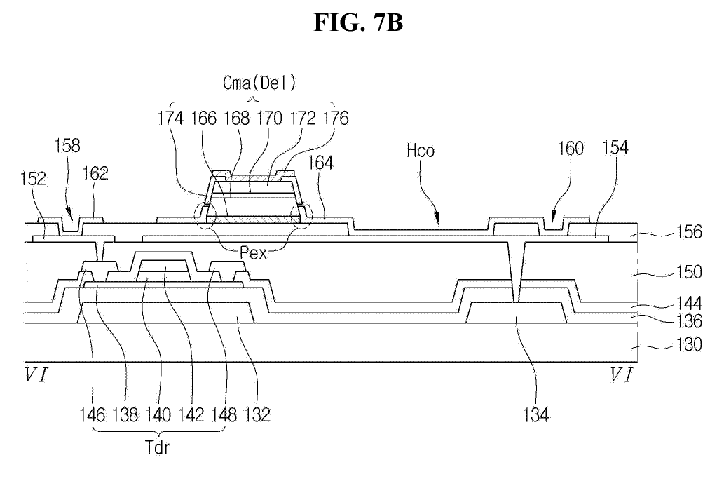

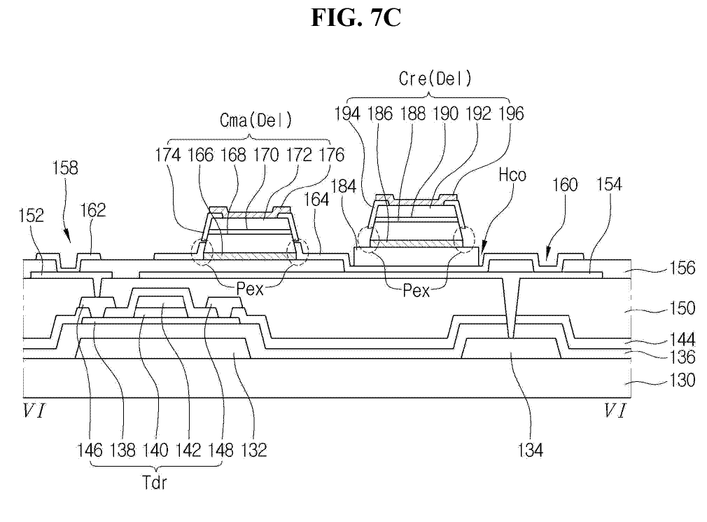

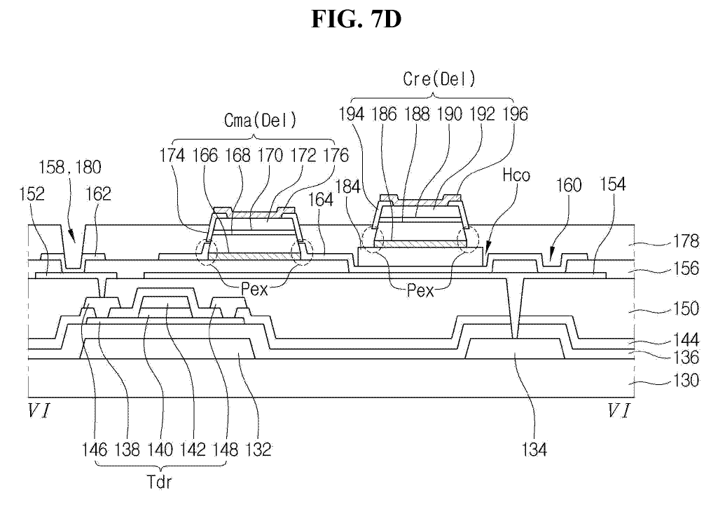

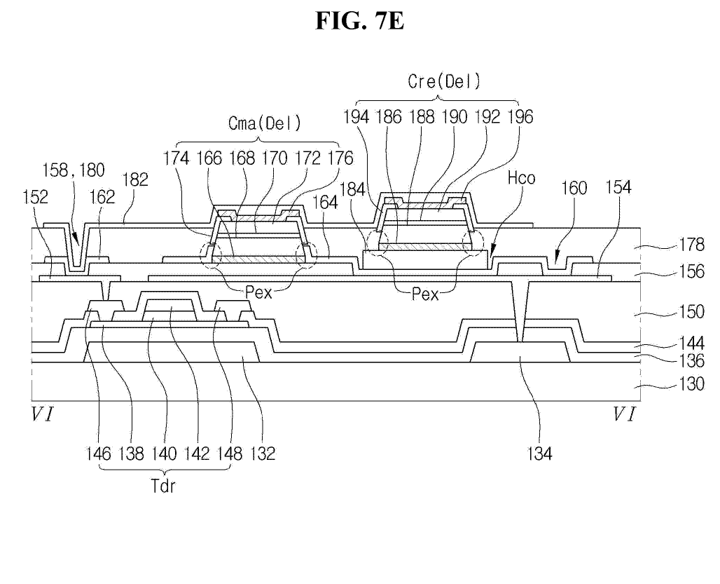

FIGS. 7A to 7E are cross-sectional views (e.g., along line VI-VI as shown in FIG. 5) showing a method of repairing a display device according to an example embodiment of the present disclosure.

In FIG. 7A, after the light shielding pattern 132 and the low level power line 134 are formed in each of the first, second, and third subpixels SP1, SP2, and SP3 on the substrate 130, the buffer layer 136 is formed on the light shielding pattern 132 and the low level power line 134 over the entire substrate 130.

Next, after the semiconductor layer 138 is disposed on the buffer layer 136 to overlap the light shielding pattern 132, the gate insulating layer 140 is formed on a central portion of the semiconductor layer 138.

Next, after the gate electrode 142 is formed on the gate insulating layer 140 to overlap the channel region of the semiconductor layer 138, the interlayer insulating layer 144 is formed on the gate electrode 142 over the entire substrate 130.

Next, after the source electrode 146 and the drain electrode 148 spaced apart from each other are formed on the interlayer insulating layer 144, the first planarizing layer 150 is formed on the source electrode 146 and the drain electrode 148 over the entire substrate 130.

The source electrode 146 and the drain electrode 148 are connected to the source region and the drain region, respectively, of the semiconductor layer 138 through contact holes in the interlayer insulating layer 144.

The semiconductor layer 138, the gate electrode 142, the source electrode 146, and the drain electrode 148 may constitute the driving transistor Tdr.

Next, after the first and second connecting electrodes 152 and 154 spaced apart from each other are formed on the first planarizing layer 150, the adhesive layer 156 is formed on the first and second connecting electrodes 152 and 154 over the entire substrate 130.

The first connecting electrode 152 is connected to the source electrode 146 through a contact hole in the first planarizing layer 150, and the second connecting electrode 154 is connected to the low level power line 134 through a contact hole in the first planarizing layer 150, the interlayer insulating layer 144, and the buffer layer 136.

The adhesive layer 156 has the first contact hole 158 exposing the first connecting electrode 152, the second contact hole 160 exposing the second connecting electrode 154, and the compensating hole Hco exposing the second connecting electrode 154.

Next, the main chip Cma of the light emitting diode Del is attached to the adhesive layer 156 between the first contact hole 158 and the compensating hole Hco.

The main chip Cma, in this example as a vertical-type light emitting diode Del, includes the first main electrode 166, the first main semiconductor layer 168, the main active layer 170, the second main semiconductor layer 172, the main passivation layer 174, and the second main electrode 176 sequentially on the adhesive layer 156.

In FIG. 7B, after the third connecting electrode 162 is formed on the adhesive layer 156 to overlap the first contact hole 158, the fourth connecting electrode 164 spaced apart from the third connecting electrode 162 is formed on the adhesive layer 156 to overlap the second contact hole 160 and the compensating hole Hco. In addition, the fourth connecting electrode 164 is disposed at a periphery of the main chip Cma and is connected to the side surface of the first main electrode 166 and the lower portion of the side surface of the first main semiconductor layer 168 through the side exposing portion Pex of the main passivation layer 174.

Next, after voltages (e.g., the low level supply voltage Vss and the high level supply voltage Vdd) are supplied to the first and second main electrodes 166 and 176 of the main chip Cma of each of the first, second, and third subpixels SP1, SP2, and SP3 using a means such as a probe, a lighting test for determining whether a light is emitted from the main chip Cma of each of the first, second, and third subpixels SP1, SP2, and SP3 is performed.

Where the main chip Cma operates normally to emit a light in the lighting test, the repair chip Cre is not attached to the fourth connecting electrode 164 in the compensating hole Hco in the corresponding one of the first, second, and third subpixels SP1, SP2, and SP3.

As shown in FIG. 7C, where the main chip Cma operates abnormally and fails to emit light in the lighting test, the conductive bonding layer 184 is formed on the fourth connecting electrode 164 in the compensating hole Hco of the adhesive layer 156, and the repair chip Cre is attached to the conductive bonding layer 184.

The repair chip Cre, in this example as a vertical-type light emitting diode Del, includes the first repair electrode 186, the first repair semiconductor layer 188, the repair active layer 190, the second repair semiconductor layer 192, the repair passivation layer 194, and the second repair electrode 196 sequentially on the conductive bonding layer 184.

In FIG. 7D, the second planarizing layer 178 is formed on the third and fourth connecting electrodes 162 and 164, at least a portion of the main chip Cma, and at least a portion of the repair chip Cre over the entire substrate 130.

The second planarizing layer 178 has the third contact hole 180 exposing the third connecting electrode 162. Also, a part of the main passivation layer 174 of the main chip Cma, the second main electrode 176, a part of the repair passivation layer 194 of the repair chip Cre, and the second repair electrode 196 are exposed through the second planarizing layer 178.

Since the fourth connecting electrode 164, the conductive bonding layer 184, and the repair chip Cre are sequentially formed on the second connecting electrode 154 exposed through the compensating hole Hco of the adhesive layer 156, a step difference generated by the repair chip Cre is at least partially compensated for. Therefore, the lower portion of the side surface of the first repair semiconductor layer 188 exposed through the side exposing portion Pex of the repair passivation layer 194 can be covered with the second planarizing layer 178 and not be exposed through the second planarizing layer 178.

In FIG. 7E, the fifth connecting electrode 182 is formed on the second planarizing layer 178 to overlap the third connecting electrode 162, the main chip Cma, and the repair chip Cre.

The fifth connecting electrode 182 is connected to the third connecting electrode 162 through the third contact hole 180 and is connected to the second main electrode 176 of the main chip Cma and the second repair electrode 196 of the repair chip Cre exposed through the second planarizing layer 178.

The lower portion of the side surface of the first repair semiconductor layer 188 exposed through the side exposing portion Pex of the repair passivation layer 194 is covered with the second planarizing layer 178 and is not exposed through the second planarizing layer 178. As a result, connection between the fifth connecting electrode 182 and the lower portion of the side surface of the first repair semiconductor layer 188 is blocked, and such failure as an electric short between the second repair electrode 196 and the lower portion of the side surface of the first repair semiconductor layer 188 (e.g., through the side exposing portion Pex of the repair passivation layer 194) can be prevented or suppressed so that a repair rate can be improved.

Next, an additional planarizing layer or an encapsulating layer may be further formed on the fifth connecting electrode 182 over the entire substrate 130 for preventing or suppressing permeation of oxygen or moisture.

In the display device 110 according to an example embodiment of the present disclosure, where the main chip Cma of any of the first, second, and third subpixels SP1, SP2, and SP3 is determined to operate abnormally (e.g., fails to emit light), the conductive bonding layer 184 and the repair chip Cre are sequentially disposed on the fourth connecting electrode 164 in the compensating hole Hco of the adhesive layer 156. The light emitting diode Del of the repair chip Cre, instead of the main chip Cma, receives a hole(s) from the driving transistor Tdr through the first connecting electrode 152, the third connecting electrode 162, and the fifth connecting electrode 182 and receives an electron(s) from the low level power line 134 through second connecting electrode 154, the fourth connecting electrode 164, and the conductive bonding layer 184 to emit light. As a result, the main chip Cma operating abnormally may be repaired with the repair chip Cre operating normally.

In addition, since the fourth connecting electrode 164, the conductive bonding layer 184, and the repair chip Cre are sequentially disposed on the second connecting electrode 154 in the compensating hole Hco of the adhesive layer 156, a step difference generated by the repair chip Cre can be at least partially compensated for. Therefore, the lower portion of the side surface of the first repair semiconductor layer 188 exposed through the side exposing portion Pex of the repair passivation layer 194 can be covered with the second planarizing layer 178 and not be exposed through the second planarizing layer 178. As a result, connection between the fifth connecting electrode 182 and the lower portion of the side surface of the first repair semiconductor layer 188 is blocked, and such failure as an electric short between the second repair electrode 196 and the lower portion of the side surface of the first repair semiconductor layer 188 can be prevented or suppressed so that a repair rate can be improved.

It will be apparent to those skilled in the art that various modifications and variation may be made in the present disclosure without departing from the scope of the disclosure. Thus, it is intended that the present disclosure cover the modifications and variations of this disclosure, including where they come within the scope of the appended claims and their equivalents.

What is claimed is:

1. A display device, comprising:
a substrate including a subpixel having a light emitting diode;
a transistor and a power line on the substrate;
a first planarizing layer on the transistor and the power line;
a first connecting electrode and a second connecting electrode on the first planarizing layer, the first and second connecting electrodes being connected to the transistor and the power line, respectively;
an adhesive layer on the first and second connecting electrodes, the adhesive layer having a compensating hole exposing the second connecting electrode;
a main chip of the light emitting diode on the adhesive layer;
a third connecting electrode on the adhesive layer, the third connecting electrode being connected to the first connecting electrode;
a fourth connecting electrode on the adhesive layer, the fourth connecting electrode being connected to the second connecting electrode through the compensating hole and connected to the main chip; and
a second planarizing layer on the third and fourth connecting electrodes.

2. The display device of claim 1, further comprising a fifth connecting electrode on the second planarizing layer, the fifth connecting electrode connected to the third connecting electrode and the main chip.

3. The display device of claim 2, wherein the main chip comprises:
a first main electrode on the adhesive layer;
a first main semiconductor layer on the first main electrode;
a main active layer on the first main semiconductor layer;
a second main semiconductor layer on the main active layer;
a main passivation layer on the second main semiconductor layer, the main passivation layer having a first exposing portion exposing a side surface of the first main electrode and a lower portion of a side surface of the first main semiconductor layer; and
a second main electrode on the main passivation layer and connected to the second main semiconductor layer.

4. The display device of claim 3, wherein the fourth connecting electrode is connected to the side surface of the first main electrode and the lower portion of the side surface of the first main semiconductor layer exposed through the first exposing portion of the main passivation layer.

5. The display device of claim 3, wherein:
the fifth connecting electrode is connected to the second main electrode exposed through the second planarizing layer; and
the fifth connecting electrode is connected to the transistor via the third connecting electrode and the first connecting electrode.

6. The display device of claim 3, further comprising:
a conductive bonding layer on and connected to the fourth connecting electrode in the compensating hole; and
a repair chip of the light emitting diode on and connected to the conductive bonding layer.

7. The display device of claim 6, wherein the repair chip comprises:
a first repair electrode on the conductive bonding layer;
a first repair semiconductor layer on the first repair electrode;
a repair active layer on the first repair semiconductor layer;
a second repair semiconductor layer on the repair active layer;
a repair passivation layer on the second repair semiconductor layer, the repair passivation layer having a second exposing portion exposing a side surface of the first repair electrode and a lower portion of a side surface of the first repair semiconductor layer; and
a second repair electrode on the repair passivation layer and connected to the second repair semiconductor layer through an opening in the repair passivation layer.

8. The display device of claim 7, wherein the second planarizing layer covers the side surface of the first repair electrode and the lower portion of the side surface of the first repair semiconductor layer exposed through the second exposing portion of the repair passivation layer.

9. The display device of claim 7, wherein an upper surface of the second planarizing layer is disposed higher than the second exposing portion of the repair passivation layer and is disposed lower than an upper surface of the second main semiconductor layer.

10. The display device of claim 7, wherein the fifth connecting electrode is connected to the second repair electrode exposed through the second planarizing layer.

11. The display device of claim 1, wherein:
the adhesive layer further has a first contact hole exposing the first connecting electrode and a second contact hole exposing the second connecting electrode; and
the third and fourth connecting electrodes are connected to the first and second connecting electrodes through the first and second contact holes, respectively.

12. The display device of claim 11, further comprising:
a fifth connecting electrode on the second planarizing layer and connected to the main chip,
wherein the second planarizing layer has a third contact hole exposing the third connecting electrode, and
wherein the fifth connecting electrode is connected to the third connecting electrode through the third contact hole.

13. The display device of claim 11, wherein:
the compensating hole in the adhesive layer is disposed laterally between the first contact hole and the second contact hole in the adhesive layer; and
the main chip is disposed on the adhesive layer laterally between the first contact hole and the compensating hole.

14. A display device having a plurality of subpixels, the display device comprising in one of the subpixels:
a transistor and a power line on a substrate;
a first connecting electrode on and connected to the transistor;
a second connecting electrode on and connected to the power line;
an adhesive layer on the first and second connecting electrodes, the adhesive layer including a compensating hole exposing the second connecting electrode;
a main light emitting diode chip on the adhesive layer;
a third connecting electrode on the adhesive layer, the third connecting electrode being connected to the first connecting electrode and the main light emitting diode chip; and
a fourth connecting electrode on the adhesive layer, the fourth connecting electrode being connected to the second connecting electrode through the compensating hole and connected to the main light emitting diode chip.

15. The display device of claim 14, wherein:
the adhesive layer further includes a first contact hole exposing the first connecting electrode and a second contact hole exposing the second connecting electrode; and
the third connecting electrode is connected to the first connecting electrode via the first contact hole, and the fourth connecting electrode is connected to the second connecting electrode via the second contact hole and the compensating hole.

16. The display device of claim 15, wherein:
the main light emitting diode chip is disposed on the adhesive layer laterally between the first contact hole and the compensating hole; and
the compensating hole is disposed laterally between the main light emitting diode chip and the second contact hole.

17. The display device of claim 14, wherein the main light emitting diode chip comprises:
a first main electrode on the adhesive layer;
a first main semiconductor layer on the first main electrode;
a main active layer on the first main semiconductor layer;
a second main semiconductor layer on the main active layer;
a main passivation layer on the second main semiconductor layer, the main passivation layer having a first exposing portion exposing a side surface of the first main electrode and a lower portion of a side surface of the first main semiconductor layer; and
a second main electrode on the main passivation layer and connected to the second main semiconductor layer.

18. The display device of claim 17, wherein:
the fourth connecting electrode is connected to the side surface of the first main electrode and the lower portion of the side surface of the first main semiconductor layer exposed through the first exposing portion of the main passivation layer; and
the third connecting electrode is connected to the second main electrode.

19. The display device of claim 14, further comprising:
a first planarizing layer on the transistor and the power line;
a second planarizing layer on the third connecting electrode, the adhesive layer, and the fourth connecting electrode; and
a fifth connecting electrode connected to the transistor and the main light emitting diode chip,
wherein the first and second connecting electrodes are on the first planarizing layer and are connected respectively to the transistor and the power line via respective contact holes through the first planarizing layer, and
wherein the fifth connecting electrode is connected to the third connecting electrode via a contact hole in the second planarizing layer and is connected to the main light emitting diode chip via an opening in the second planarizing layer.

20. The display device of claim 14, further comprising:
a conductive bonding layer on and connected to the fourth connecting electrode in the compensating hole; and
a repair light emitting diode chip on the conductive bonding layer and connected to the third connecting electrode and the fourth connecting electrode.

21. The display device of claim 20, wherein the repair light emitting diode chip comprises:
a first repair electrode on the conductive bonding layer;
a first repair semiconductor layer on the first repair electrode;
a repair active layer on the first repair semiconductor layer;
a second repair semiconductor layer on the repair active layer;
a repair passivation layer on the second repair semiconductor layer, the repair passivation layer having a second exposing portion exposing a side surface of the first repair electrode and a lower portion of a side surface of the first repair semiconductor layer; and
a second repair electrode on the repair passivation layer and connected to the second repair semiconductor layer through an opening in the repair passivation layer.

22. The display device of claim 21, further comprising:
a planarizing layer on the third connecting electrode, the adhesive layer, the fourth connecting electrode, and the conductive bonding layer,
wherein the planarizing layer covers the side surface of the first repair electrode and the lower portion of the side surface of the first repair semiconductor layer exposed through the second exposing portion of the repair passivation layer, and
wherein an upper surface of the planarizing layer is positioned above the second exposing portion of the repair passivation layer.
